(19) United States
(12) Patent Application Publication
(10) Pub. No.: US 2025/0362618 A1
(43) Pub. Date: Nov. 27, 2025

(54) METHOD FOR CHARACTERIZING A MEASUREMENT APPARATUS FOR SEMICONDUCTOR LITHOGRAPHY AND MEASUREMENT APPARATUS

(71) Applicant: Carl Zeiss SMT GmbH, Oberkochen (DE)

(72) Inventors: Stephan Ratzsch, Jena (DE); Roman Schmeissner, Weimar (DE)

(21) Appl. No.: 19/212,944

(22) Filed: May 20, 2025

(30) Foreign Application Priority Data
May 28, 2024 (DE) 102024114896.9

(51) Int. Cl. G03F 7/00

(52) U.S. Cl. CPC G03F 7/706837; G03F 7/706839

(57) ABSTRACT

Disclosed is a method for characterizing a measurement apparatus for semiconductor lithography, comprising the following steps:
performing a plurality of measurements, in particular of a marker property or die property (for example, registration values or CD values)
determining a relationship between the width of a confidence interval of the measurement result from averaging and the number of elements of a subset of all the measurements carried out. Also disclosed is a measurement apparatus in which the method is applied.

### CROSS REFERENCE TO RELATED APPLICATIONS

The present application claims the priority of the German patent application DE 10 2024 114 896.9 of May 28, 2024, the content of which is fully incorporated herein by reference.

### TECHNICAL FIELD

This disclosure relates to a method for characterizing a measurement apparatus for semiconductor lithography, in particular for examining confidence intervals of the measurements of registration and inspection of photomasks. This disclosure furthermore relates to a measurement apparatus.

### BACKGROUND

Various systems are available for the process control of the production of DUV and EUV lithography masks. The shared feature of these systems and the methods used is that the highest possible reproducibility of the measurement results should be achieved. The measurement variables ascertained by the aforementioned systems are based in particular on the positions of edges of structures arranged on the masks, which positions are determined by optical microscopy.

The following relationship applies in simplified form: The position R of a structure on a photomask is obtained using the positions of two opposite edges A and B in the image as R=(A+B)/2. The deviation of the actual position from the predetermined position is referred to as registration.

In the context of mask inspection, the so-called critical dimension (CD) is considered by means of a so-called CD measurement system. It is obtained using measured edges as CD=|A−B|. In this context, a critical dimension is in particular the distance between opposite points on an edge, for example for circular structures, or on two edges, for example of a line-type structure on a mask. The CD is used in particular in connection with the characterization of periodic structures, for example so-called “lines and spaces”.

In the general case of any structures to be measured (dies) with a high number of edges, alternative methods can be used for the determination of registration and CD. The possibilities are then the use of symmetry properties or the comparison with simulated image data. However, the analogy described above remains.

For the determination of the registration or CD, a relevant measurement region (or region of interest—ROI) is defined in each aerial image recording. Within this region of interest, the image information consisting of one or more recordings in different focus positions is evaluated.

The registration and CD measurement methods are also similar in terms of limiting physical effects. Examples include optical diffraction effects, imaging quality and optical shot noise. For both applications, an improvement in the reproducibility of registration and CD measurements is desirable.

An essential quality feature of the measurements made is the confidence interval of a single measurement. Under the assumption of normally distributed measured values, the 3-sigma interval of repeated measurements is usually used for this purpose. The 3-sigma interval is the interval in which 99.7% of the results of an independent single scan lie. The width of the interval is thus a measure of the reproducibility and reliability of registration and CD measurements.

Furthermore, a distinction is made between static and dynamic reproducibility. In the first case, the photomask remains in a given position for repeated measurements. In the case of dynamic reproducibility, the mask is repositioned in the measurement field or moved from one measurement position to another before the actual measurement.

Usually, a system for mask registration measurements is used to calibrate apparatuses for the production of photomasks for semiconductor lithography, so-called mask writers, or to check their functioning during operation.

For a registration measurement, a coordinate system on the photomask is usually defined in a first step. For this purpose, applied markers, the so-called alignment markers, are used. In the simplest case, the edge of the mask can also be regarded as such an alignment marker.

In a second step, the positions of special registration markers or dies in this coordinate system are measured. Other markers are used to ensure the alignment of masks relative to one another or to a projection exposure apparatus during the production process of semiconductor elements. These markers are referred to as scanner alignment markers. All structures on the photomask are generated by electron beam or laser beam writers.

For the assessment of the performance of a mask registration tool, the so-called maximum 3-sigma registration is determined as follows. The method is illustrated in FIG. 1.

In the example shown, a so-called site xi is shown in Partial FIG. 1A. A site is a target object (alignment markers, registration markers, dies or scanner alignment markers) for which the position or a distance is to be determined. A site corresponds to a target position on the mask. At this point, one or more images in different focus positions are typically recorded and evaluated. In order to reach the target position, a so-called stage moves the photomask within the measurement microscope of the mask registration tool. The stage moves in the x/y direction and in this way travels successively to individual sites.

A measurement run in which a large number of sites are successively travelled to is called a loop. In the use case, a loop that is symbolized in FIG. 1B by an arrow with the reference sign 11 is typically measured on a mask.

In order to assess the reproducibility of the measurements of a tool, i.e. to characterize the tool after installation or maintenance, a plurality of loops, for example 10 loops, are usually performed. For each site, this results in 10 measured values as registration data in nanometres. These data can be plotted in a histogram (FIG. 1C).

This allows determination of the 3-sigma registration for each individual site. To assess the reproducibility of a registration measurement, the maximum of all 3-sigma registrations, or max-3-sigma registrations for short, is determined for all the sites of a reference mask (FIG. 1D). The value is both a performance indicator for the tool and a confidence interval for a 1-loop individual measurement performed by the user. Typical are 100 to 400 sites homogeneously distributed over the mask.

One difficulty regarding registration measurements on photomasks is in particular that the individual structures of interest, registration markers or dies can vary in size. The structures to be measured can be very small, in particular smaller than the resolution limit of the registration tool. Due to the imaging properties of the optical measurement system, the max-3-sigma registration deteriorates significantly at size scales close to and below the resolution limit. In some cases, the requirements for measurement, in particular in the case of DUV and EUV lithography, can no longer be met with the solutions known from the prior art.

Conversely, for large structures (dies), for example, registration markers with line widths of greater than 1 μm, comparatively good values for the max-3-sigma registration can be achieved. Currently the target is a value of approx. 0.1 nm max-3-sigma. However, this value cannot be achieved with the solutions known from the prior art.

In addition, there is a conflict of objectives between the achievable max-3-sigma registration and the throughput that is still possible, i.e. the number of measured structures per unit of time. In general, increasing optical intensity, integration time of the camera and the number of images measured per site can improve reproducibility.

A similar situation exists for systems for mask inspection. Such systems are used to assess any writing errors of photomasks regarding their influence on the imaging result on the wafer. The relevant measurement dimension is the structure width or critical dimension (CD). A match with or a differentiation from the target value determines the usability of a mask or the need for correction or repair.

In analogy to a registration measurement system, a confidence interval of a measurement that is as small as possible should be achieved here as well (repeatability). In this case, the corresponding 3-sigma confidence interval is the reproducibility of the CD determination (CD reproducibility). Determination of the 3-sigma-CD for a large number of sites is the subject of the tool acceptance after installation or maintenance. Typically, only one loop is measured on a mask in the use case.

A large number of loops, such as 180, are measured to assess the reproducibility of the measurements of a CD measurement system. This results for each site in 180 measured values as measurements of the CD in nanometres. These data can be plotted in a histogram, and for each individual site the 3-sigma of the CD, or 3-sigma-CD for short, can be determined. The value of the dynamic 3-sigma-CD for all relevant test sites is a performance indicator for the tool and at the same time a confidence interval for a 1-loop individual measurement performed by the user.

One difficulty regarding CD measurements on photomasks is that the individual structures of interest can vary in size and shape. The variation of the shapes is highly diverse and depends on the use case. They can be periodic or aperiodic in nature. Typically, periodically repeating contact holes or lines with spaces are considered.

The structures to be measured can be very small, in particular smaller than the resolution limit of the CD measurement system. Due to the imaging properties of the optical measurement system, 3-sigma-CD deteriorates greatly at size scales close to and below the resolution limit. In some cases, the requirements for measurement, in particular in the case of DUV and EUV lithography, can no longer be met with the solutions known from the prior art.

However, to reduce the 3-sigma-CD, a plurality of images are recorded during one site and averaged before the evaluation. This can reduce the confidence interval, the 3-sigma-CD. For structure sizes determined at the mask level, close to the resolution limit of the CD measurement system, there is a lower limit of the 3-sigma-CD with the current prior art.

For the reduction of the dispersion of measurement results of the registration and CD, in general, averaging can be considered. Under certain conditions, the standard deviation of mean values of equally sized subsets of the original measurement series is smaller than the standard deviation of the original measurement data. The relationship applies to any mean values of two or more measured values. The standard deviation is reduced by an increase in the number of averaged individual measurements (weak law of large numbers).

In other words, the standard deviation (confidence interval) of a measurement task can be reduced by running the underlying measurement itself several times and averaging the results. The mean values of the individual measurements are regarded as the result of a newly defined measurement specification.

The above approach for reducing the standard deviation of a measurement specification is not always applicable in practice and cannot be scaled as required. Prerequisites for the noise properties of the measurement system must be met so as to average their influence during the measurement period. For the duration of the individual measurements, the spectral properties of the noise must be invariant and the frequency range of the noise must be sufficiently high.

The reproducibility of registration and CD measurements is limited by system properties such as mask positioning accuracy and optical shot noise. The latter noise intrinsically meets the requirements for reducing variance by averaging: It has a high bandwidth (white noise) and is stationary.

In turn, the influence of time-dependent external factors on the accuracy of the averaged measurement increases with the number of possibly averaged measurement results. Such influencing factors typically have unfavourable averaging behaviour.

Due to the high complexity of a tool for mask registration or CD determination, it is not possible or very complicated to quantitatively predict the averaging properties of the system measurement based on noise properties of the system modules. This is a problem solved by certain embodiments disclosed herein.

### SUMMARY

An object of certain embodiments disclosed herein is to provide a quantitative assessment and estimation of the attainability of the lowest possible max-3-sigma registration (registration measurement system) and 3-sigma-CD even below the previous limits. In particular, a possible optimum should be taken into account by combining dynamic and static measurements.

In general, in one aspect, disclosed is a method for characterizing a measurement apparatus for semiconductor lithography, i.e., for example, a CD measurement system or a registration measurement system, that comprises the following steps:
performing a plurality of measurements, in particular of a marker property or die property (for example, registration values or CD values)
determination of a relationship between the width of a confidence interval of the measurement result from averaging and the thickness, i.e. the number of elements in a subset of the measured values used for all measurements.

Embodiments utilize the following relationship: The above-described effect of reducing the standard deviation of measurement data by averaging can be quantitatively assessed using the Allan deviation (and its square root, the Allan deviation) and/or its variants. [D. W. Allan, Statistics of Atomic Frequency Standards, Proceedings of the IEEE Vol. 54, No. 2, 1966] [Vanier, Audoin, The Quantum Physics of Atomic Frequency Standards, Institute of Physics Publishing, 1989].

The application of the principle of averaging measurement data relating to the photomask registration and CD determination has so far only been done empirically or implicitly. Embodiments disclosed herein enable, for the first time, a quantitative assessment of the influences on confidence intervals.

This makes it possible to quantitatively estimate the potential of reducing the max-3-sigma registration or 3-sigma-CD by increasing the number of individual measurements. It is possible to check the necessary prerequisites at the system level. A complex statistical analysis of the system properties is therefore not necessary for the measurement data at the system level.

The Allan variance comprises an algorithm that can be used to characterize the extent to which the standard deviation of a measurement series decreases (or whether it decreases at all) depending on the number of averaged individual measurements. Furthermore, the Allan variance allows an estimation of the number of averaged measured values starting from which the standard deviation no longer decreases. Based on the course of the Allan variance, the properties of the noise limiting the measurement can also be inferred.

Optimized values for the parameters M and N can be ascertained in particular for a specific measurement scenario, for example for a specific tool configuration and/or a die to be measured, by means of the method, wherein
N is a number of individual measurements on a target object (site)
M is a number of measurement runs (loops).

For the purpose of simultaneously optimizing the confidence intervals of the measurement and throughput, sets of M and N can be ascertained for different structures to be measured on a photomask. In this context, very small structures such as lines and spaces close to or below the resolution limit of the tool constitute a borderline case.

Another borderline case is the global registration measurement of the measurement of registration markers distributed over the entire mask. In this case, a value of 1 is expected for the parameter M and a value greater than 1 for the parameter N.

In another aspect, disclosed is a measurement apparatus for determining properties of photomasks for semiconductor lithography that comprises a control unit, which is configured to apply the method described above.

In this case, the measurement apparatus may comprise an input apparatus by means of which a user can choose among different measurement methods. For example, a high-precision method may be offered to a user. The parameters of the high-precision method can be selected by means of the method described above in such a way that a number of individual measurements and/or loops is selected, starting from which the confidence interval is no longer significantly improved by an increase in the number of individual measurements.

### DESCRIPTION OF DRAWINGS

This disclosure is explained in greater detail below with reference to the drawing. In the drawing:

FIG. 1 shows in partial FIGS. 1A to 1D a method for assessing the performance of a mask registration tool according to the prior art (already explained),

FIG. 2 shows a flowchart for explaining the new method, and

FIG. 3 shows an example of a plot for a so-called Allan deviation.

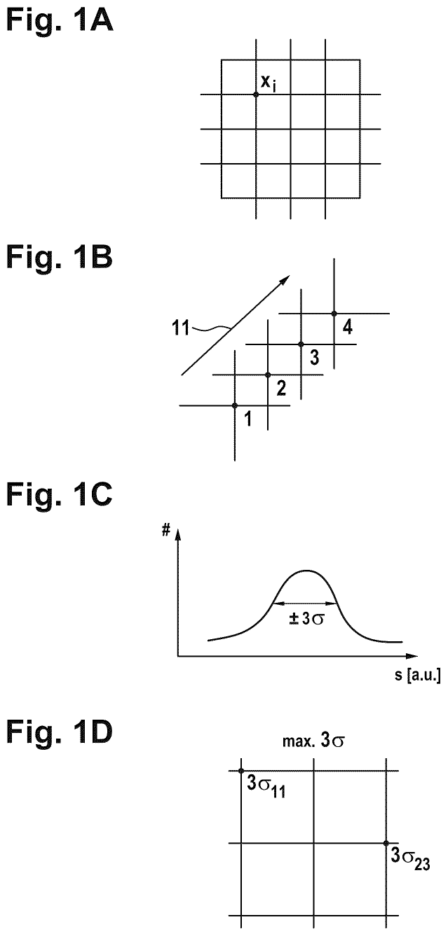

### DETAILED DESCRIPTION

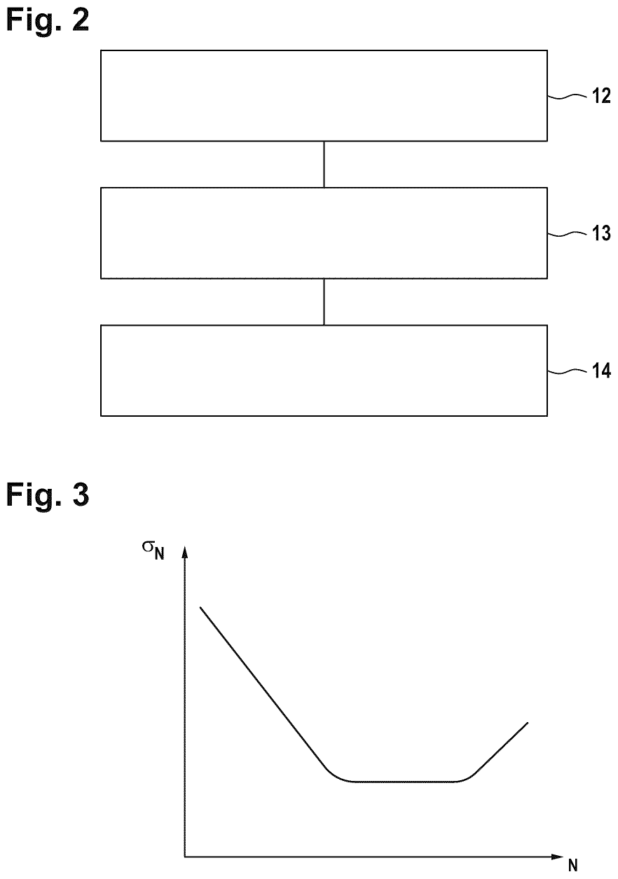

FIG. 2 shows an exemplary application of the method using a flowchart. In a phase of characterizing a measurement apparatus, a large number (for example between 10 and 200) of similar dynamic and static registration or CD measurements are carried out in a first step (denoted in the figure by the reference sign 12). In the case of registration, a loop is the special case of a dynamic measurement.

The max-3-sigma registration or 3-sigma-CD Allan deviation of the registration or CD data which depends on the number of considered measurements is determined in a second step (denoted in the figure by the reference sign 13) for all sites by a software function. It is output in the form of a table or a curve. The Allan deviation is the square root of the Allan variance. It replaces the max-3-sigma in the system assessment and determines the confidence interval of the averaged result of N individual measurements per site as max-3-adev registration or 3-adev-CD. For the purpose of a dimensional connection, 3-sigma is identical to 3-adev for a single measurement.

The result of the characterization measurement is illustrated in FIG. 3. The Allan deviation is plotted as a function of the averaged number N of measured values. The curve can be used to check whether the given measuring instrument can achieve the objectives of reproducibility (confidence interval). A curve proportional to the reciprocal of the root of the number of measurements indicates white noise limiting the measurement. In the case of an optical measurement system, checks are in this way carried out as to the fact that optical and not electronic, mechanical or thermal effects limit the reproducibility of the measurement. For the purpose of this analysis, the software provides an interpolation function. The best achievable value is given by a horizontal line in the log-log plot of the Allan variance. If the number of averaged values is increased further, the Allan deviation increases again. The increase allows conclusions to be drawn about drifts of the registration or CD measurement. The software automatically evaluates the curve in terms of initial rise, minimum value and limiting drift. The method for assessing curves of the Allan deviation is prior art for atomic clocks. It is part of certain embodiments to apply this method to mask registration and inspection tools and to automate it.

In the context of the distinction between static and dynamic reproducibility (in particular in the CD measurement system) and with the objective of optimizing throughput and reproducibility, a three-dimensional representation can also be used. The Allan deviation of the measurement is plotted and assessed as a function of the parameters N (static measurement) and M (dynamic measurement).

In this context, the averaging of a plurality of individual measurements as a new measurement achieves significantly smaller confidence intervals for measurement results than the previous prior art. However, the effective measurement throughput of the tool in sites per hour decreases accordingly.

Against the background of the conflict of objectives of throughput versus the required confidence interval of the measurement results, the optimum number of measurement repetitions (N static, M dynamic) for the configuration of the measurement apparatus that is relevant for the application can be determined in a third step (denoted in FIG. 2 with the reference sign 14). Configurations include in particular intensity, exposure time, number of frames in the focus stack, and stop settings in the optical image representation. Furthermore, this optimum number of averagings is greatly dependent on the dimensions (CDs) of the dies to be measured (registration markers). For structures far greater than the resolution limit of the tool, a minimum max-3-adev registration or 3-adev-CD is expected after just a few measurements. For structures close to and smaller than the resolution limit, a higher number of averagings is expected until system limitation is reached. In contrast to the prior art, in the case of N>1, not only one measurement per measurement position is carried out.

In this context, static measurement is in particular the recording of a focus stack of one or more images and interpolation of the registration in the best focus plane. The repetition of the measurement of a site in this manner is automatically carried out by the control software of the measurement apparatus with fixed or adjustable repetition parameters.

Alternatively, without optimizing throughput, a variant of the application comprises the automatic measurement and averaging of multiple loops using tool software to improve the confidence interval of the measurement data (M dynamic measurement). The averaging of the measurement data per site is also carried out automatically by the software in this case. The configuration of static and dynamic repetition (N, M) which is optimum for the measurement system is ascertained in the context of the objectives repeatability and measurement throughput using the Allan deviation.

In the case of one application for a registration measurement system, the application of a repeated static measurement is suitable in particular for so-called global registration measurements in which the measurement takes place over an entire mask. In this case, N>1 and M=1.

In the case of the registration of smaller structures—a so-called local registration measurement (LRM)—a very large number of dies in an image field (site) and a number of adjacent (stitched) sites are measured. This results in very large amounts of image data to be evaluated, which are transmitted to an external computer cluster and evaluated there. In this measurement scenario, the throughput relevance of the travel paths fades into the background; and the duration of the data evaluation is the decisive factor. An exemplary embodiment is the performance of a large number of repetitions of the optical measurement (static, dynamic or combined) with evaluation and automatic averaging in offline processing. This is not expected to cause a significant disadvantage in terms of throughput.

There is an application for the CD measurement system that combines detection of CD defects with the assessment of printability in a resist at the wafer level. This method is called the wafer level critical dimension (in short: WLCD). An aerial image of the structure of the mask is generated at different points of the mask and the CD of the structure is predicted at wafer level. In this use case, primarily periodic structures (contact holes or lines and trenches) are measured. An evaluation of various relevant regions of interest in an optical image according to the described method would be conceivable if it shows only a periodic structure, which is relatively small with respect to the image size. This would increase the computing time, but not the measurement time of the device.

Using an optimal combination of dynamic and static measurement of a periodic structure, it could then be specified with a very small 3-sigma-CD.

As a result of the embodiments described herein, for example, a “high-precision mode” of a measurement apparatus can be provided for registration and CD measurements. With a reduced throughput, an improved confidence interval of the result data is achieved. The user does not have to perform a statistical evaluation (mean value or similar) himself, but this is provided automatically by the software. The software also provides functions for tool characterization in the sense of the Allan deviation and thus allows the acceptance of any performance specifications of the tool.

### Electronic Implementations

The subject matter and the actions and operations described in this specification can be implemented in digital electronic circuitry, in tangibly-embodied computer software or firmware, in computer hardware, including the structures disclosed in this specification and their structural equivalents, or in combinations of one or more of them. The subject matter and the actions and operations described in this specification can be implemented as or in one or more computer programs, e.g., one or more modules of computer program instructions, encoded on a computer program carrier, for execution by, or to control the operation of, data processing apparatus. The carrier can be a tangible non-transitory computer storage medium. Alternatively or in addition, the carrier can be an artificially generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

The term “data processing apparatus” encompasses all kinds of apparatus, devices, and machines for processing data, including by way of example a programmable processor, a computer, or multiple processors or computers. Data processing apparatus can include special-purpose logic circuitry, e.g., an FPGA (field programmable gate array), an ASIC (application specific integrated circuit), or a GPU (graphics processing unit). The apparatus can also include, in addition to hardware, code that creates an execution environment for computer programs, e.g., code that constitutes processor firmware, a protocol stack, a database management system, an operating system, or a combination of one or more of them.

A computer program can be written in any form of programming language, including compiled or interpreted languages, or declarative or procedural languages; and it can be deployed in any form, including as a stand alone program, e.g., as an app, or as a software module, component, engine, subroutine, or other unit suitable for executing in a computing environment, which environment may include one or more computers interconnected by a data communication network in one or more locations.

A computer program may, but need not, correspond to a file in a file system. A computer program can be stored in a portion of a file that holds other programs or data, e.g., one or more scripts stored in a markup language document, in a single file dedicated to the program in question, or in multiple coordinated files, e.g., files that store one or more modules, sub programs, or portions of code.

The processes and logic flows described in this specification can be performed by one or more computers executing one or more computer programs to perform operations by operating on input data and generating output. The processes and logic flows can also be performed by special-purpose logic circuitry, e.g., an FPGA, an ASIC, or a GPU, or by a combination of special-purpose logic circuitry and one or more programmed computers.

Computers suitable for the execution of a computer program can be based on general or special-purpose microprocessors or microcontrollers or a combination of them, or any other kind of central processing unit. Generally, a central processing unit will receive instructions and data from a read only memory or a random access memory or both. The essential elements of a computer are a central processing unit for executing instructions and one or more memory devices for storing instructions and data. The central processing unit and the memory can be supplemented by, or incorporated in, special-purpose logic circuitry.

Generally, a computer will also include, or be operatively coupled to, one or more mass storage devices, and be configured to receive data from or transfer data to the mass storage devices. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

To provide for interaction with a user, the subject matter described in this specification can be implemented on one or more computers having, or configured to communicate with, a display device, e.g., a LCD (liquid crystal display) monitor, or a virtual-reality (VR) or augmented-reality (AR) display, for displaying information to the user, and an input device by which the user can provide input to the computer, e.g., a keyboard and a pointing device, e.g., a mouse, a trackball or touchpad. Other kinds of devices can be used to provide for interaction with a user as well; for example, feedback and responses provided to the user can be any form of sensory feedback, e.g., visual, auditory, speech, or tactile feedback or responses; and input from the user can be received in any form, including acoustic, speech, tactile, or eye tracking input, including touch motion or gestures, or kinetic motion or gestures or orientation motion or gestures. In addition, a computer can interact with a user by sending documents to and receiving documents from a device that is used by the user; for example, by sending web pages to a web browser on a user's device in response to requests received from the web browser, or by interacting with an app running on a user device, e.g., on a smartphone or electronic tablet. Also, a computer can interact with a user by sending text messages or other forms of message to a personal device, e.g., a smartphone that is running a messaging application, and receiving responsive messages from the user in return.

The term “configured to” may be used herein in connection with systems, apparatus, and computer program components. That a system of one or more computers is configured to perform particular operations or actions means that the system has installed on it software, firmware, hardware, or a combination of them that in operation cause the system to perform the operations or actions. That one or more computer programs is configured to perform particular operations or actions means that the one or more programs include instructions that, when executed by data processing apparatus, cause the apparatus to perform the operations or actions. That special-purpose logic circuitry is configured to perform particular operations or actions means that the circuitry has electronic logic that performs the operations or actions.

The subject matter described in this specification can be implemented in a computing system that includes a back end component, e.g., as a data server, or that includes a middleware component, e.g., an application server, or that includes a front end component, e.g., a client computer having a graphical user interface, a web browser, or an app through which a user can interact with an implementation of the subject matter described in this specification, or any combination of one or more such back end, middleware, or front end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some implementations, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

Other aspects, embodiments, and advantages are within the scope of the following claims.

What is claimed is:

1. A method for characterizing a measurement apparatus for semiconductor lithography, comprising the following steps:
performing a plurality of measurements
determining a relationship between the width of a confidence interval of the measurement result from averaging and the number of elements of the subset of the measured values used for all measurements carried out.

2. The method of claim 1,
characterized in that
an Allan deviation is ascertained to determine the relationship between the width of the confidence interval and the number of measured values.

3. The method of claim 1,
characterized in that
the measured values are registration values of a photomask.

4. The method of claim 1,
characterized in that
the measured values are CD values of structures on a photomask.

5. The method of claim 2,
characterized in that
an automated mathematical analysis of the curve of the Allan deviation is performed, wherein at least one of the following parameters is determined:
origin of the curve for 1 measuring point
initial increase
minimum
extrapolated increase for a large number of measurements.

6. The method of claim 5,
characterized in that
using the mathematical evaluation of the Allan deviation, conclusions are drawn about the properties of the measurement tool, in particular
noise properties
drift properties
optimum time windows for measurements.

7. The method of claim 1,
characterized in that
using the method, optimized values for the parameters M and N are determined for a specific measurement scenario, wherein
N is a number of individual measurements on a target object (site)
M is a number of measurement runs (loops).

8. The method of claim 7,
characterized in that
sets of M and N determined for specific structures to be measured on a photomask can be ascertained.

9. The method of claim 7,
characterized in that
for one envisaged global registration measurement, a combination of values from 1 to 10 (N) and 1 to 10 (M) is defined for the parameters N and M.

10. A measurement apparatus for determining properties of photomasks for semiconductor lithography,
characterized in that
the measurement apparatus comprises a control unit, which is configured to apply the method according to claim 1.

11. The measurement apparatus of claim 10,
characterized in that
the measurement apparatus is an apparatus for determining registration.

12. The measurement apparatus of claim 10,
characterized in that
the measurement apparatus is an apparatus for determining the critical dimension (CD).

13. The measurement apparatus of claim 10,
characterized in that
the measurement apparatus comprises an input apparatus by means of which a user can choose among different measurement methods.

14. The measurement apparatus of claim 13,
characterized in that
one of the measurement methods is a high-precision method.
